(19) United States
(12) Patent Application Publication
(10) Pub. No.: US 2009/0257208 A1
(43) Pub. Date: Oct. 15, 2009

(54) COMPACT PACKAGING FOR POWER AMPLIFIER MODULE

(76) Inventors: Zlatko Filipovic, Palo Alto, CA (US); Weiping Wang, Palo Alto, CA (US)

Correspondence Address: XIN WEN, 3449 RAMBOW DRIVE, PALO ALTO, CA, 94306, US

(21) Appl. No.: 12/101,003

(22) Filed: Apr. 10, 2008

(51) Int. Cl. H05K 1/18

(52) U.S. Cl. 361/760

(57) ABSTRACT

A semiconductor die for power amplification includes a substrate comprising a front surface and a back surface, a power amplifier on the front surface of the substrate and is configured to amplify an input signal received at an input node and to output an amplified signal at an output node; a first electric terminal on the front surface of the substrate, wherein the first electric terminal is electrically coupled to the input node of the power amplifier; a second electric terminal on the back surface of the substrate, and a first via that runs from the front surface to the back surface of the substrate and electrically connects the first terminal and the second electric terminal. The second electric terminal can receive the input signal that is to be received by the input node of the power amplifier.

### BACKGROUND

The present invention relates to radio frequency power amplifiers.

Portable devices such as laptop personal computers, Personal Digital Assistant and cellular phones with wireless communication capability are being developed in ever decreasing size for convenience of use. Correspondingly, the electrical components thereof must also decrease in size while still providing effective radio transmission performance. However, the substantially high transmission power associated with radio frequency (RF) communication increases the difficulty of miniaturization of the transmission components.

A major component of a wireless communication device is the power amplifiers. A power amplifier can be fabricated on a semiconductor integrated circuit chip to provide signal amplification with substantial power. The power amplifier chip can be interconnected with certain off-chip components such as inductors, capacitors, resistors, and transmission lines for operation controls and for providing impedance matching to the input and output RF signals.

Packaging presents a significant challenge to the applications of power amplifiers. Packaging for power amplifiers should be reliable, and can prevent damages to the power amplifiers. Packaging also needs to provide proper cooling and grounding to the power amplifiers.

### SUMMARY

In a general aspect, the present invention relates to a semiconductor die for power amplification. The semiconductor die includes a substrate comprising a front surface and a back surface; a power amplifier on the front surface of the substrate and configured to amplify an input signal received at an input node and to output an amplified signal at an output node; a first electric terminal on the front surface of the substrate, wherein the first electric terminal is electrically coupled to the input node of the power amplifier; a second electric terminal on the back surface of the substrate; a first via that runs from the front surface to the back surface of the substrate and electrically connects the first terminal and the second electric terminal, wherein the second electric terminal can receive the input signal that is to be received by the input node of the power amplifier; a third electric terminal on the front surface of the substrate, wherein the third electric terminal is configured to receive the amplified signal from the output node of the power amplifier; a fourth electric terminal on the back surface of the substrate; and a second via that runs from the front surface to the back surface of the substrate and electrically connects the third terminal and the fourth electric terminal, wherein the fourth electric terminal can receive the amplified signal from the output node of the power amplifier.

In another general aspect, the present invention relates to a power-amplifier module comprising a semiconductor die that includes a substrate comprising a front surface and a back surface; a power amplifier on the front surface of the substrate and configured to amplify an input signal received at an input node and to output an amplified signal at an output node; a first electric terminal on the front surface of the substrate, wherein the first electric terminal is electrically coupled to the input node of the power amplifier; a second electric terminal on the back surface of the substrate; a first via that runs from the front surface to the back surface of the substrate and electrically connects the first terminal and the second electric terminal, wherein the second electric terminal can receive the input signal that is to be received by the input node of the power amplifier; a third electric terminal on the front surface of the substrate, wherein the third electric terminal is configured to receive the amplified signal from the output node of the power amplifier; a fourth electric terminal on the back surface of the substrate; and a second via that runs from the front surface to the back surface of the substrate and electrically connects the third terminal and the fourth electric terminal, wherein the fourth electric terminal can receive the amplified signal from the output node of the power amplifier. The power-amplifier module also includes a die carrier having a first surface bonded to the back surface of the semiconductor die, wherein the die carrier comprises a first electric pad and a second electric pad on the first surface, wherein the first electric pad is electrically conductively bonded to the second electric terminal on the back surface of the substrate, and wherein the second electric pad is electrically conductively bonded to the fourth electric terminal on the back surface of the substrate.

Implementations of the system may include one or more of the following. The first via can include a hole that runs from the first terminal on the front surface to the second electric terminal on the back surface of the substrate; and a conductive material disposed in the hole to provide electric connection between the first terminal on the front surface and the second electric terminal on the back surface of the substrate. The conductive material can include Al, Cu, or Au. The second via can include a hole that runs from the third terminal on the front surface to the fourth electric terminal on the back surface of the substrate; and a conductive material disposed in the hole to provide electric connection between the third terminal on the front surface and the fourth electric terminal on the back surface of the substrate. The semiconductor die can further include a power sensing circuit on the front surface of the substrate, wherein the power sensing circuit is configured to detect the amplified signal and to produce a power sensing signal; a fifth electric terminal on the front surface of the substrate and configured to receive the power sensing signal from the power sensing circuit; a sixth electric terminal on the back surface of the substrate; and a third via that runs from the front surface to the back surface of the substrate and electrically connects the fifth terminal and the sixth electric terminal, which allows the sixth electric terminal to receive the power sensing signal. The semiconductor die can further include a biasing circuit on the front surface of the substrate, wherein the biasing circuit is configured to produce a biasing signal to the power amplifier in response to a control signal; a fifth electric terminal on the front surface of the substrate and coupled to the power sensing circuit; a sixth electric terminal on the back surface of the substrate; and a third via that runs from the front surface to the back surface of the substrate and electrically connects the fifth terminal and the sixth electric terminal, wherein the sixth electric terminal is configured to receive the control signal to be received by the biasing circuit. The semiconductor die can further include a fifth electric terminal on the front surface of the substrate and configured to provide power to the power amplifier; a sixth electric terminal on the back surface of the substrate; and a third via that runs from the front surface to the back surface of the substrate and electrically connects the fifth terminal and the sixth electric terminal, wherein the sixth electric terminal is configured to receive power for power amplifier. The semiconductor die can further include a fifth electric terminal on the back surface of the substrate, wherein the fifth electric terminal is electrically connected to the ground for power amplifier. The substrate can include InGaP GaAs. The substrate can include one or more Heterojunction Bipolar Transistors.

Embodiments may include one or more of the following advantages. The packaged power amplifier module described in the present specification is more compact than some conventional packaged power amplifier modules. The described packaged power amplifier module can better protect the power amplifier module from damages and is thus more reliable than some conventional packaged power amplifier modules. The described packaged power amplifier module provides improved cooling and appropriate grounding to the power amplifier circuit. The described packaged power amplifier module is also easier and takes less time to test.

### BRIEF DESCRIPTION OF THE DRAWINGS

The following drawings, which are incorporated in and from a part of the specification, illustrate embodiments of the present specification and, together with the description, serve to explain the principles of the specification.

FIG. 1 is a perspective view of a power amplifier module packaged using wire bond technologies.

FIG. 2A is a perspective view of a semiconductor die containing an integrated power amplifier circuit.

FIG. 2B is a bottom view of the semiconductor die of FIG. 2A.

FIG. 3 is an exemplified integrated power amplifier circuit compatible with the semiconductor die in FIGS. 2A and 2B.

FIG. 4A is a top perspective view of a die carrier for the semiconductor die of FIGS. 2A and 2B.

FIG. 4B is a bottom view of the die carrier in FIG. 4A.

FIG. 5 is a perspective view illustrating the application of conductive adhesive on the metal pads on the die carrier.

FIG. 6 is a perspective view illustrating the bonding of the semiconductor die of FIGS. 2A and 2B to the die carrier of FIGS. 4A and 4B.

FIG. 7 is a perspective view of an assembly of the semiconductor die on the die carrier after the bonding step shown in FIG. 6.

FIG. 8 is a perspective view of a packaged power amplifier module comprising an enclosure for the assembly of the semiconductor die on the die carrier shown in FIG. 7.

### DETAILED DESCRIPTION

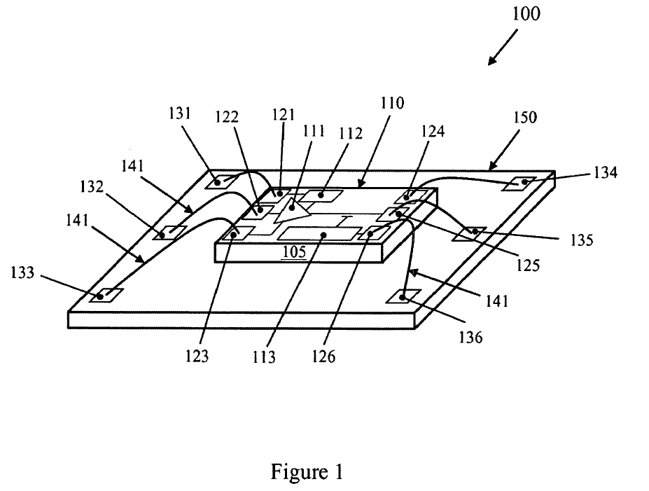

Referring to FIG. 1, a power amplifier module 100 includes a semiconductor die 110 bonded to a die carrier 150. The semiconductor die 10 includes an integrated power amplifier circuit fabricated on a substrate 150 and suitable for a wireless communication device. The power-amplifier die 110 can include a power amplifier 111, a biasing circuit 112 that can provide bias voltage or current to the power amplifier 111, and a power sensing circuit 113 configured to detect the output RF signals. The integrated power amplifier circuit in the power-amplifier die 110 is typically constructed from a semiconductor substrate. For wireless power amplifiers, the integrated power amplifier circuit typically comprises hetero-junction bipolar transistors (HBTs) formed on an InGaP GaAs substrate.

The power-amplifier die 110 can also include a plurality of electric terminals 121-126 for receiving, outputting, manipulating, and enhancing RF signals. For example, the electric terminal 124 can receive power (VCC) for the power amplifier circuit. The electric terminal 122 can receive an input RF signal from outside and to be amplified by the power amplifier 111. The electric terminal 125 can output an amplified RF signal output by the power amplifier 111. The electric terminal 121 can receive a bias control signal for controlling the biasing circuit 112. The electric terminal 126 can output a power sensing signal produced by the power sensing circuit 113. The power-amplifier die 110 can include other electric terminal (e.g. 123) for inputting or outputting other signals. The die carrier 150 includes a plurality of electric pads 131-136 that are respectively connected to the electric terminals 121-126 by conductive wires 140 (i.e. wire bonding). The electric pads 131-136 can electrically connect to external circuit(s) outside of the power amplifier module 100 to receive or output the above described RF signals.

The power amplifier module shown in FIG. 1 includes several drawbacks. The connective wires connecting the electric pads on the die carrier and the electric terminals on the power-amplifier die are easily damaged during wire soldering, and during handling or operation of the power amplifier module, which makes the power amplifier module unreliable. Additionally, the implementation of wire bonding also requires the die carrier to be much larger than the power-amplifier die, which increases the foot print of the power amplifier module. Moreover, testing of the power-amplifier die is time consuming and expensive. Since the electric terminals on the power-amplifier die are closely positioned and difficult to access, the testing signals can only be connected to the electric pads on the die carrier after the wire bonding is completed.

Flip chip technologies have been applied to packaging of planar CMOS semiconductor dies, which can reduce package size compared with conventional wire bonding. Flip chip packaging is not suitable for packaging HBTs on an InGaP GaAs substrate that includes uneven surfaces on the device side of the die (i.e. the top surface in FIG. 1). HBT device usually includes three dimensional structures that are formed by etching during device fabrication. A flip chip packaging of a HBT/GaAs-based power-amplifier die will create large gaps between the device surface and the die carrier, which prevents adequate cooling during operation.

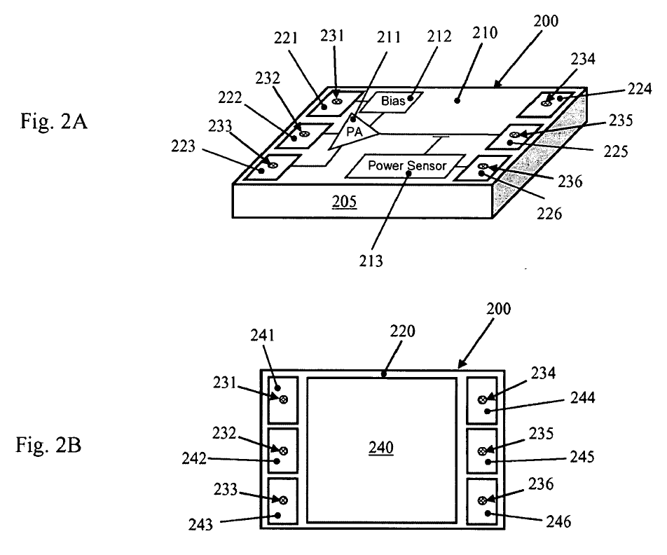

To overcome the above described drawbacks, referring to FIGS. 2A and 2B, a power amplifier module 200 includes a substrate 205 which includes a front surface 210 and a back surface 220. An integrated power amplifier circuit suitable for a wireless communication device is fabricated on the front surface 210. The wireless communication device can be compatible with one or multiple communication standards and protocols such as Orthogonal Frequency-Division Multiplexing (OFDM), Orthogonal Frequency-Division Multiplexing Access (OFDMA), Code Division Multiple Access (CDMA), Wideband Code Division Multiple Access (WCDMA), High-Speed Downlink Packet Access (HSDPA), High-Speed Packet Access (HSPA), Ultra Mobile Broadband (UMB), Long Term Evolution (LTE), WiMax, WiBro, WiFi, WLAN, and others. The power-amplifier die 200 can include a power amplifier 211, a biasing circuit 212 that can provide bias voltage or current to the power amplifier 211, and a power sensing circuit 213 configured to detect the output RF signals. The integrated power amplifier circuit in the power-amplifier die 200 is typically constructed from a semiconductor substrate such ashetero-junction bipolar transistors (HBTs) formed on an InGaP GaAs substrate.

The power-amplifier die 200 also includes a plurality of electric terminals 221-226 on the front surface 210 for receiving or outputting RF signals. The electric terminals 221-226 can be made of Au, Cu, Al, or other conductive materials. For example, the electric terminal 224 can receive power (VCC) for the power amplifier circuit. The electric terminal 222 can receive an input RF signal from outside and to be amplified by the power amplifier 211. The electric terminal 225 can output an amplified RF signal output by the power amplifier 211. The electric terminal 221 can receive a bias control signal for controlling the biasing circuit 212. The electric terminal 226 can output a power sensing signal produced by the power sensing circuit 213. The power-amplifier die 200 can include other electric terminal (e.g. 223) for inputting, outputting, or controlling the same or other signals. The controlling functions can include current reduction, gain control, power sensing, bias control, control matching, and mode changing, etc.

The back surface 220 of the power-amplifier die 200 also includes a plurality of electric terminals 241-246, each of which is positioned under one of the electric terminals 221-226. A plurality of inter-connect vias 231-236 connect the electric terminals 221-226 with their respective electric terminals 241-246. For example, the via 231 runs through from the electric terminal 221 on the front surface 210 to the electric terminals 241 on the back surface 220. The hole of the via 231 can be filled by a conductive material using PVD or electroplating. A metallic material such as Au, Cu, or Al can be disposed in the hole by deposition or electroplating. The electric terminal 221 on the front surface 210 and the electric terminal 241 on the back surface 220 are thus electrically connected. Likewise, each of the electric terminals 222-226 on the front surface 210 is also connected to its respective electric terminal 242-246 on the back surface 220. Additionally, a large conductive pad 240 on the back surface 220 is connected to the ground of the integrated power amplifier circuit by one or more vias (not shown) on the front surface 210 of the power-amplifier die 200. In some embodiments, the conductive pad 240 is positioned in the center while the electric terminals 241-246 are positioned near the edges of the back surface 220 of the power-amplifier die 200.

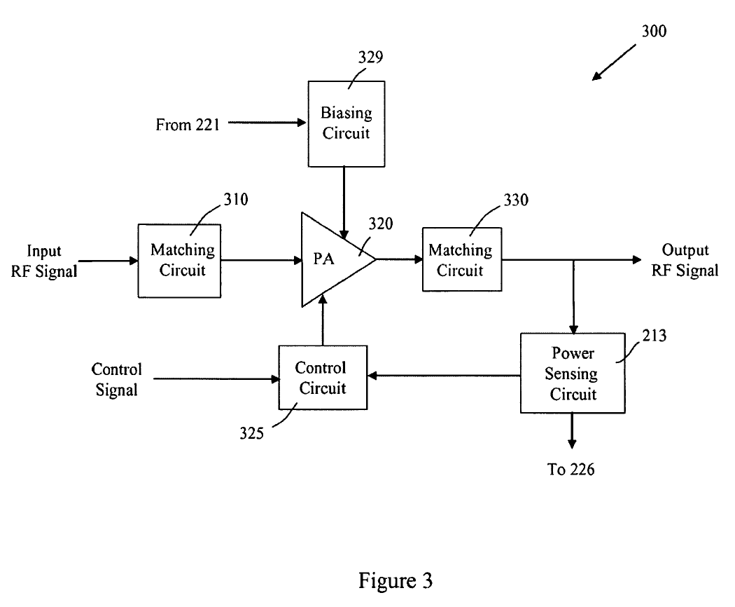

The power-amplifier die 200 is compatible with different configurations of power amplifier circuits. For example, the power-amplifier die 200 can include more than one or multi-stage power amplifier. Each power amplifier can be biased by a separate biasing circuit. Referring to FIG. 3, an exemplified power amplifier circuit 300 compatible with the power-amplifier die 200 includes a matching circuit 310, a power amplifier 320 having an input node and an output node, a control circuit 325. The matching circuit 310 can receive an input RF signal. The matching circuit 31 0 can match the input impedance to the impedance of the device that provides the input signal and send an impedance matched signal to the power amplifier 320. The control circuit 325 can provide gain and phase controls to the power amplifier 320. The power amplifier 320 is biased by a biasing circuit 329 that can be internal in the power amplifier 320. The power amplifier 320 can receive the signal from the matching circuit 310 at its input node, amplify it, and produce an amplified signal at its output node. The amplified signal is sent to the matching circuit 330. The matching circuit 330 can match the impedance of the amplified signal and produce an output signal. Other details of impedance matching circuits and power amplifier modules are described commonly assigned U.S. Pat. No. 6,633,005, filed on Oct. 22, 2001, titled “Multilayer RF Amplifier Module”, by Ichitsubo, et al., the content of which is incorporated by reference.

The power sensing circuit 213 can receive the output signal from the matching circuit 330, which can detect the power, the gain, and the phase of the output RF signal for linearity control. The power sensing circuit 213 can send a sensing signal to the control circuit 325 or to a different controller in response to the output RF signal. Other details of the power sensor circuit are disclosed in commonly assigned U.S. patent application Ser. No. 10/385,059, titled “Accurate Power Sensing Circuit for Power Amplifiers” filed Mar. 9, 2003, by Ichitsubo et al., the content of which is incorporated herein by reference.

The control circuit 325 can receive control signals from a controller that can be a base band processor or a dedicated linearity control circuit. The control signals can include Vmode control signal and power control signal. The control signals can, for example, be received at electric terminal 223 on the power-amplifier die 200. The control circuit 325 can improve gain linearity by compensating the gain expansion and compression between different stages of power amplifiers. The control circuit 325 can also correct or compensate for phase variations over a range of the output power.

The power amplifier circuit in the power-amplifier die 200 can maintain excellent output linearity and a constant gain (the ratio of the output signal power level to the input signal power level) over a wide output range. The quality of digital communication, especially the quality degrades at high output power level, can commonly be measured by Error Vector Magnitude (EVM), Bit Error Rate (BER), Packet Error Rate (PER), and Adjacent Channel Power Ratio (ACPR). Other details of the power amplifier circuit compatible with the power-amplifier die are disclosed in commonly assigned U.S. patent application Ser. No. 11/858,106 tilted “Multi-band amplifier module with harmonic suppression” filed Sep. 19, 2007, by Ichitsubo et al., the content of which is incorporated herein by reference.

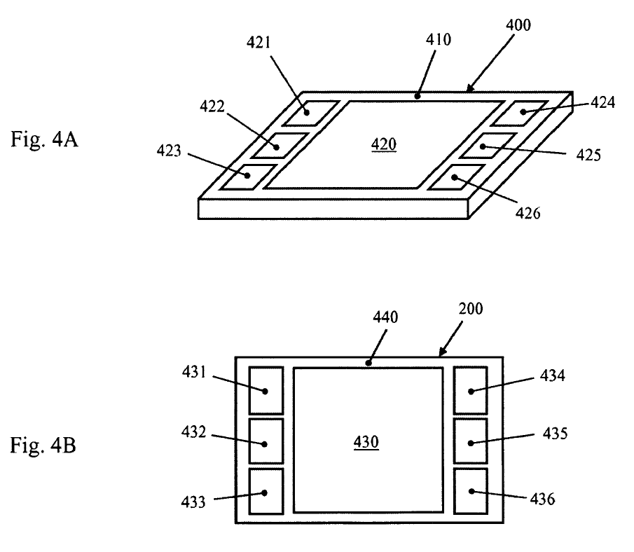

Referring to FIG. 4A, a die carrier 400 includes a plurality of electric pads 421-426 and a conductive pad 420 on its front surface 410. The lateral dimensions of the die carrier 400 can be substantially the same or slightly larger than the respective lateral dimensions of the power-amplifier die 200. The die carrier 400 is designed to allow its front surface 410 to be bonded to the back surface 220 of the power-amplifier die 200. The electric pads 421-426 and the conductive pad 420 can be formed by a metallic material such as Cu, Al, or Au. The die carrier 400 having the electric pads 421-426 and the conductive pad 420 on the front surface 410 can be formed by lead frame (LTCC) or by multi-layer printed circuit board (PCB). The electric pads 421-426 on the front surface 410 of the die carrier 400 are positioned to exactly match the locations of the electric terminals 241-246 on the back surface 220 of the power-amplifier die 200. Similarly, the conductive pad 420 is also positioned to exactly seal to the conductive pad 240 when the back surface 220 of the power-amplifier die 200 is bonded to the front surface 410 of the die carrier 400.

Referring to FIG. 4B, the back surface 440 of the die carrier 400 can include a plurality of mounting electric pads 431-436 and 440 that are electrically connected respectively to the electric pads 421-426 and the conductive pad 420 on the front surface 410 of the die carrier 400. The mounting electric pads 431-436 and 440 are configured to be mounted or connected to an external circuit on a substrate such as a printed circuit board which incorporates the power-amplifier die 200 as a component.

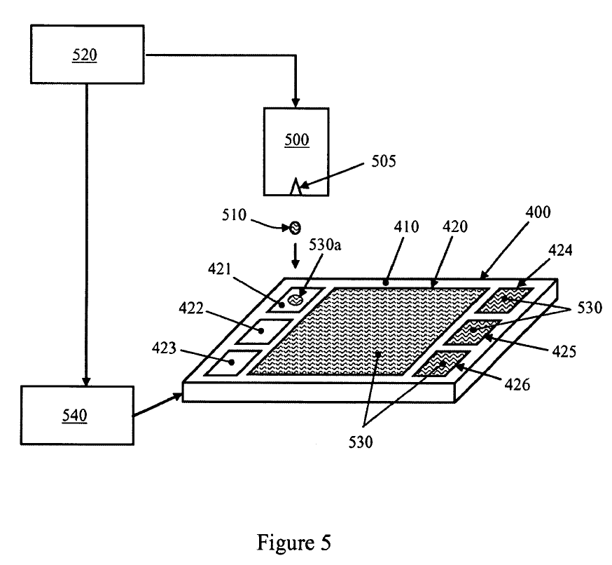

The bonding of the power-amplifier die 200 to the die carrier 400 can be implemented by applying an adhesive material at the bonding interfaces. The adhesive material can be applied to the bonding interfaces using a variety of techniques. For example, referring to FIG. 5, the die carrier 400 is positioned under a fluidic delivery device 500 that has a nozzle 505 configured to deliver a fluidic conductive adhesive under the control of a controller 520. Suitable conductive adhesive include a polymer adhesive and a metallic material, such as Ag epoxy. The die carrier 400 can be transported by a transport mechanism 540 in both lateral directions. The transport mechanism 540 can include for example digital stepper motors or DC motors. The die carrier 400 is moved by the transport mechanism 540 so that each of the electric pads 421-426 and the conductive pad 420 on the front surface 410 is sequentially positioned under the fluidic delivery device 500. The fluidic delivery device 500 delivers a droplet 510 of the conductive adhesive to form a deposited drop 530a of conductive adhesive on, for example, the electric pad 421. Multiple deposited drops 530a can form a layer 530 of conductive adhesive on the electric pads 421-426 and the conductive pad 420 on the front surface 410.

The bonding to the power amplifier die to the die carrier can be implemented by applying the conductive adhesives to the electric pads on the back surface. The application of the conductive adhesive can be implemented by different means such as screen printing. The bonding between the power amplifier die and the die carrier can also be accomplished by other methods. The bonding to the power amplifier die to the die carrier can be implemented using a sheet patterned with a polymeric conductive adhesive layer. The sheet can be sandwiched and pressured between the power amplifier die to the die carrier. The polymeric conductive adhesive can be activated by heat to produce the bonding.

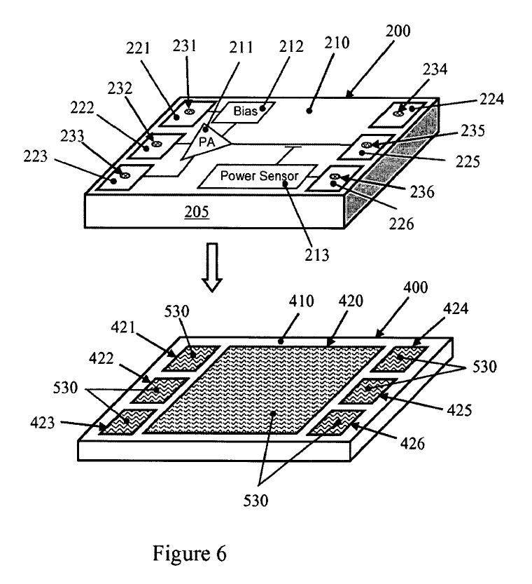

After the layer 530 of conductive adhesive on the electric pads 421-426 and the conductive pad 420, referring to FIG. 6, the back surface 220 of the power-amplifier die 200 is brought to contact and pressed against to front surface 410 of the die carrier 400. The electric pads 421-426 and the conductive pad 420 on the front surface 410 of the die carrier 400 are respectively securely bonded to the electric terminals 241-246 and the conductive pad 240 on the back surface 220 of the power-amplifier die 200.

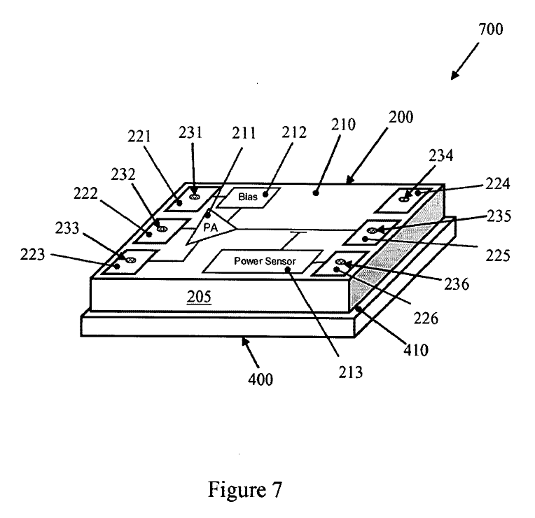

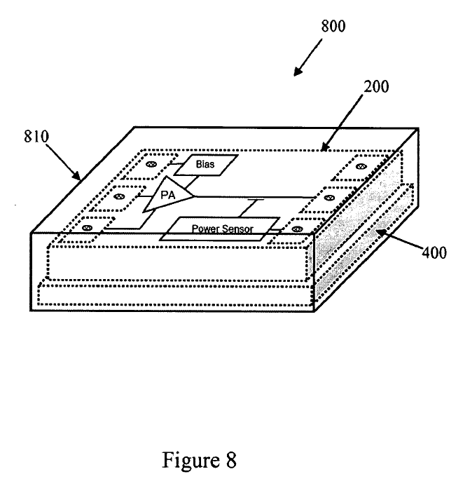

As a result, an assembly 700 comprising the power-amplifier die 200 and the die carrier 400 is formed, as shown in FIG. 7. The electric pads 421-426 on the die carrier 400 are therefore respectively electrically connected to the electric terminals 221-226 on the front surface 210 of the power-amplifier die 200. The assembly 700 can be further sealed by an encapsulation cover 810, shown in FIG. 8, to form a packaged power amplifier module 800. The encapsulation cover 810 can be sealed, for example, to the side surfaces of the die carrier 400. The encapsulation cover 810 can also be sealed to the front surface 410 of the die carrier 400. The power-amplifier die 200 on the die carrier 400 is therefore encapsulated and protected by the encapsulation cover 810.

An advantage of the assembly 700 and the packaged power amplifier module 800 is that the bonding step is much simpler and of much lower probability for damages compared to the conventional wire bonding techniques. Another advantage of the assembly 700 and the packaged power amplifier module 800 is that they allow easy (RF) testing of the power amplifier die 200. The electric pads 421-426 on the front surface 410 of the die carrier 400 are designed to be easily connected to external circuits for receiving test control signals and outputting amplified signals from the power amplifiers for analysis. The packaged power amplifier module 800 can be mounted on another substrate such as a PCB The electric pads 431-436 and the conductive pad 440 on the back surface 440 of the die carrier 400 can electrically connect the electric terminals 221-226 of the power amplifier die 200 to the electric circuit in the substrate.

It is understood the disclosed systems and methods are compatible with other variations without deviating from the spirit of the present application. For example, the die carrier can carry one or more power amplifier dies. The die carrier can also carry one or more dies having other functions than power amplifying in addition to a power amplifier die.

The disclosed power amplifier dies are suitable to applications in various wireless data and voice communications standards and protocols, including Orthogonal Frequency-Division Multiplexing (OFDM), Orthogonal Frequency-Division Multiplexing Access (OFDMA), Code Division Multiple Access (CDMA), Wideband Code Division Multiple Access (WCDMA), High-Speed Downlink Packet Access (HSDPA), High-Speed Packet Access (HSPA), Ultra Mobile Broadband (UMB), Long Term Evolution (LTE), WiMax, WiBro, WiFi, WLAN, 802.16, and others. The disclosed linear amplifier circuits are also suitable for high frequency operations by utilizing Gallium Arsenide Heterojunction Bipolar Transistors (GaAs HBT).

What is claimed is:

1. A semiconductor die for power amplification, comprising:
a substrate comprising a front surface and a back surface;
a power amplifier on the front surface of the substrate, wherein the power amplifier is configured to amplify an input signal received at an input node and to output an amplified signal at an output node;
a first electric terminal on the front surface of the substrate, wherein the first electric terminal is electrically coupled to the input node of the power amplifier;
a second electric terminal on the back surface of the substrate;
a first via that runs from the front surface to the back surface of the substrate and electrically connects the first terminal and the second electric terminal, wherein the second electric terminal is configured to receive the input signal that is to be received by the input node of the power amplifier;
a third electric terminal on the front surface of the substrate, wherein the third electric terminal is configured to receive the amplified signal from the output node of the power amplifier;
a fourth electric terminal on the back surface of the substrate; and
a second via that runs from the front surface to the back surface of the substrate and electrically connects the third terminal and the fourth electric terminal, wherein the fourth electric terminal is configured to receive the amplified signal from the output node of the power amplifier.

2. The semiconductor die of claim 1, wherein the first via comprises:
a hole that runs from the first terminal on the front surface to the second electric terminal on the back surface of the substrate; and
a conductive material disposed in the hole to provide electric connection between the first terminal on the front surface and the second electric terminal on the back surface of the substrate.

3. The semiconductor die of claim 1, wherein the conductive material comprises Al, Cu, or Au.

4. The semiconductor die of claim 1, wherein the second via comprises:
a hole that runs from the third terminal on the front surface to the fourth electric terminal on the back surface of the substrate; and
a conductive material disposed in the hole to provide electric connection between the third terminal on the front surface and the fourth electric terminal on the back surface of the substrate.

5. The semiconductor die of claim 1, further comprising:
a power sensing circuit on the front surface of the substrate, wherein the power sensing circuit is configured to detect the amplified signal and to produce a power sensing signal;
a fifth electric terminal on the front surface of the substrate and configured to receive the power sensing signal from the power sensing circuit;
a sixth electric terminal on the back surface of the substrate; and
a third via that runs from the front surface to the back surface of the substrate and electrically connects the fifth terminal and the sixth electric terminal, which allows the sixth electric terminal to receive the power sensing signal.

6. The semiconductor die of claim 1, further comprising:
a biasing circuit on the front surface of the substrate, wherein the biasing circuit is configured to produce a biasing signal to the power amplifier in response to a control signal;
a fifth electric terminal on the front surface of the substrate and coupled to the power sensing circuit;
a sixth electric terminal on the back surface of the substrate; and
a third via that runs from the front surface to the back surface of the substrate and electrically connects the fifth terminal and the sixth electric terminal, wherein the sixth electric terminal is configured to receive the control signal to be received by the biasing circuit.

7. The semiconductor die of claim 1, further comprising:
a fifth electric terminal on the front surface of the substrate and configured to provide power to the power amplifier;
a sixth electric terminal on the back surface of the substrate; and
a third via that runs from the front surface to the back surface of the substrate and electrically connects the fifth terminal and the sixth electric terminal, wherein the sixth electric terminal is configured to receive power for power amplifier.

8. The semiconductor die of claim 1, further comprising:
a fifth electric terminal on the back surface of the substrate, wherein the fifth electric terminal is electrically connected to the ground for power amplifier.

9. The semiconductor die of claim 1, wherein the substrate comprises InGaP or GaAs.

10. The semiconductor die of claim 1, wherein the substrate comprises one or more Heterojunction Bipolar Transistors.

11. A power-amplifier module, comprising:
a semiconductor die for power amplification, comprising:
a substrate comprising a front surface and a back surface;
a power amplifier on the front surface of the substrate, wherein the power amplifier is configured to amplify an input signal received at an input node and to output an amplified signal at an output node;
a first electric terminal on the front surface of the substrate, wherein the first electric terminal is electrically coupled to the input node of the power amplifier;
a second electric terminal on the back surface of the substrate;
a first via that runs from the front surface to the back surface of the substrate and electrically connects the first terminal and the second electric terminal, wherein the second electric terminal is configured to receive the input signal that is to be received by the input node of the power amplifier;
a third electric terminal on the front surface of the substrate, wherein the third electric terminal is configured to receive the amplified signal from the output node of the power amplifier;
a fourth electric terminal on the back surface of the substrate; and
a second via that runs from the front surface to the back surface of the substrate and electrically connects the third terminal and the fourth electric terminal, wherein the fourth electric terminal is configured to receive the amplified signal from the output node of the power amplifier; and
a die carrier having a first surface bonded to the back surface of the semiconductor die, wherein the die carrier comprises a first electric pad and a second electric pad on the first surface, wherein the first electric pad is electrically conductively bonded to the second electric terminal on the back surface of the substrate, and wherein the second electric pad is electrically conductively bonded to the fourth electric terminal on the back surface of the substrate.

12. The power-amplifier module of claim 11, wherein the first via comprises:
a hole that runs from the first terminal on the front surface to the second electric terminal on the back surface of the substrate; and
a conductive material disposed in the hole to provide electric connection between the first terminal on the front surface and the second electric terminal on the back surface of the substrate.

13. The power-amplifier module of claim 11, wherein the conductive material comprises Al, Cu, or Au.

14. The power-amplifier module of claim 11, wherein the second via comprises:
a hole that runs from the third terminal on the front surface to the fourth electric terminal on the back surface of the substrate; and
a conductive material disposed in the hole to provide electric connection between the third terminal on the front surface and the fourth electric terminal on the back surface of the substrate.

15. The power-amplifier module of claim 11, further comprising:
a power sensing circuit on the front surface of the substrate, wherein the power sensing circuit is configured to detect the amplified signal and to produce a power sensing signal;
a fifth electric terminal on the front surface of the substrate and configured to receive the power sensing signal from the power sensing circuit;
a sixth electric terminal on the back surface of the substrate; and
a third via that runs from the front surface to the back surface of the substrate and electrically connects the fifth terminal and the sixth electric terminal, which allows the sixth electric terminal to receive the power sensing signal.

16. The power-amplifier module of claim 11, further comprising:
a biasing circuit on the front surface of the substrate, wherein the biasing circuit is configured to produce a biasing signal to the power amplifier in response to a control signal;
a fifth electric terminal on the front surface of the substrate and coupled to the power sensing circuit;
a sixth electric terminal on the back surface of the substrate; and
a third via that runs from the front surface to the back surface of the substrate and electrically connects the fifth terminal and the sixth electric terminal, wherein the sixth electric terminal is configured to receive the control signal to be received by the biasing circuit.

17. The power-amplifier module of claim 11, further comprising:
a fifth electric terminal on the front surface of the substrate and configured to provide power to the power amplifier;
a sixth electric terminal on the back surface of the substrate; and
a third via that runs from the front surface to the back surface of the substrate and electrically connects the fifth terminal and the sixth electric terminal, wherein the sixth electric terminal is configured to receive power for power amplifier.

18. The power-amplifier module of claim 11, further comprising:
a fifth electric terminal on the back surface of the substrate, wherein the fifth electric terminal is electrically connected to the ground for power amplifier.

19. The power-amplifier module of claim 11, further comprising a conductive adhesive material disposed at interfaces between the first electric pad and the second electric terminal on the back surface of the substrate, and between the second electric pad and the fourth electric terminal.

20. The power-amplifier module of claim 19, wherein the conductive adhesive material comprises a composite material comprising a polymer adhesive and a metallic material.

21. The power-amplifier module of claim 11, further comprising a cover that encapsulates the semiconductor die and at least a portion of the die carrier.

22. The power-amplifier module of claim 11, wherein the die carrier is a lead frame or a printed circuit board.

23. The power-amplifier module of claim 11, wherein the substrate comprises InGaP or GaAs.

24. The power-amplifier module of claim 11, wherein the substrate comprises one or more Heterojunction Bipolar Transistors.

25. The power-amplifier module of claim 11, wherein the die carrier comprises a second surface comprising mounting electric pads electrically connected to the first electric pad and the second electric pad on the first surface, wherein the mounting electric pads are configured to be connected to an external circuit.
